(19) United States
(12) Patent Application Publication
(10) Pub. No.: US 2006/0182996 A1
(43) Pub. Date: Aug. 17, 2006

(54) Organic EL element, method for fabricating the same and organic EL display device

(75) Inventors: Nobuhiro Nakamura, Yokohama-shi (JP); Kazuhiro Monzen, Arakawa-ku (JP); Koretomo Harada, Arakawa-ku (JP); Shinju Otani, Arakawa-ku (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: OPTREX Corporation, Arakawa-ku (JP)

(21) Appl. No.: 11/340,546

(22) Filed: Jan. 27, 2006

(30) Foreign Application Priority Data
Jan. 27, 2005 (JP) 2005-019015

(51) Int. Cl. H01L 51/50; H01L 51/56

(52) U.S. Cl. 428/690; 428/917; 428/212; 313/504; 313/506; 427/66

(57) ABSTRACT

An organic EL element is provided which is capable of restraining chrominance non-uniformity caused by a film thickness distribution of an applied film, of having good display quality, of reducing the driving voltage, and of having interlayer short-circuit endurance.

The organic EL element according to one mode of the present invention comprises an anode 11, a cathode 12, and an organic EL layer 13. The organic EL layer comprises a hole injection layer 131 and a hole transport layer 132. The hole injection layer includes organic-thin-film-forming-molecules and dopants oxidizing the organic-thin-film-forming-molecules, the dopants having a reduction potential of 0.5 to 0.85 V with respect to a standard hydrogen electrode, and the hole transport layer having an ionization potential of 8.5×10⁻¹⁹ J (5.3 eV) or below.

### BACKGROUND OF THE INVENTION

1. Filed of the Invention

The present invention relates to an organic EL (Electroluminescence) element, a method for fabricating the same and an organic EL display device, in particular a composition of the organic EL layer in an organic EL element.

2. Discussion of Background

For recent years, research and development has been actively conducted on organic EL display devices using an organic EL element. Organic EL display devices are expected to be the next generation of display devices because of having a wider viewing angle range and faster response than liquid crystal display devices and because of organic substances having a wide variety of light emission properties. An organic EL element used in organic EL display devices includes has anodes, cathodes disposed so as to confront the anodes, and an organic EL layer disposed between the anodes and the cathodes. Typically, the anodes, the organic EL layer and the cathodes are laminated in this order from a substrate surface.

The organic EL layer has a monolayered structure or a multilayered structure. When the organic EL layer has a multilayered structure, the organic EL layer includes organic thin films, such as an organic light emitting layer, a hole injection layer and a hole transport layer. The organic EL element is a current-driven display element, which emits light by itself when a current is supplied to the organic EL layer disposed between an anode and a cathode. A position where an anode, the organic EL layer and a cathode are overlapped with one another serves as a display pixel.

When organic substances are laminated on electrodes disposed on a substrate, organic materials are vacuum-deposited to form the organic thin films in some cases. In a case of vapor-depositing the organic materials, when an electrode as a underneath layer for the organic thin films has a foreign material adhering thereto, or a projection or a recess formed on a surface thereof, an organic thin film fails to be formed in a desired state because of being adversely affected by the presence of such a foreign material, a projection or a recess in some cases.

As a method for solving this problem, there has been known a wet application method (hereinbelow, referred to as the application method). The application method is a technique wherein respective organic materials for forming the respective organic thin films are dispersed or dissolved in respective liquids, and the respective organic materials are applied as the respective solutions to cover such a foreign material, a projection, a recess or the like, thereby to bring the organic thin films into a desired state. For example, JP-A-2001-351779 discloses in paragraphs 0012 to 0017 that at least one of organic thin films is formed by the application method.

Examples of the application method are an offset printing method, a relief printing method and a mask spray method. In the offset printing method and the relief printing method, a thin film, which comprises a solution containing an organic material dispersed or dissolved in a solvent, is formed only in certain areas. In the mask spray method, e.g., a glass mask or a metal mask, which has apertural areas formed therein so as to conform to desired areas, is positioned, and each solution with an organic material dispersed or dissolved therein is sprayed. In the latter case, each of the solutions is atomized by dispersing each of the solutions in a gaseous medium, such as a nitrogen gas, or by using a two-fluid nozzle or the like.

Various examples of the organic materials used in such application methods include polyparaphenylenevinylene (PPV), polythiophene and polypyrrole. On the other hand, there is a technique wherein an oxidizing agent is doped to create holes in order to improve the conductivity of a thin film formed by use of such an organic material. Examples of the oxidizing agent include Lewis acid, protonic acid, a transition metal compound, electrolyte salt, and a halogen compound.

The formation and the properties of organic thin films disposed by the application method are disclosed in, e.g., “Organic EL material Technique” Chapter 5 under the editorship of Yoshiharu SATOH, published by CMC press, May in 2004. According to this non-patent document, adequate polymer organic materials and dopants can be used to obtain not only an effect of restraining element electrodes from being short-circuited due to surface smoothness provided by the application method but also an effect of reducing the driving voltage of the element.

However, when an organic EL element contains moisture, the moisture diffuses in the organic EL element to form a non-emissive area, or the moisture in the organic EL element promotes a reduction in luminance to reduce display quality in some cases.

A dopant material used as the oxidizing agent needs to have oxidizability enough to be capable of oxidizing an applied organic material as well as having a tendency to have higher moisture absorption as the oxidizability becomes higher. Accordingly, it is preferred to use dopants having low moisture absorption, i.e., dopants having low oxidizability in order to avoid an adverse effect caused by moisture in an organic EL element. Such dopants having low moisture absorption may comprise an organic acid, such as benzenesulfonic acid and toluenesulfonic acid.

However, the inventors have found that when dopants having low moisture absorption as stated above is used, display non-uniformity becomes prominent according to the thickness distribution of an applied film. In this regard, detailed explanation will be made. First, ITO was used to dispose anodes, and a spray method was utilized to dispose a layer of PTPDEK (represented by Chemical Formula 2), using TBPAH (represented by chemical Formula 1) as dopants. On the layer of PTPDEK, a hole transport layer was disposed, using PPD (represented by Chemical Formula 3).

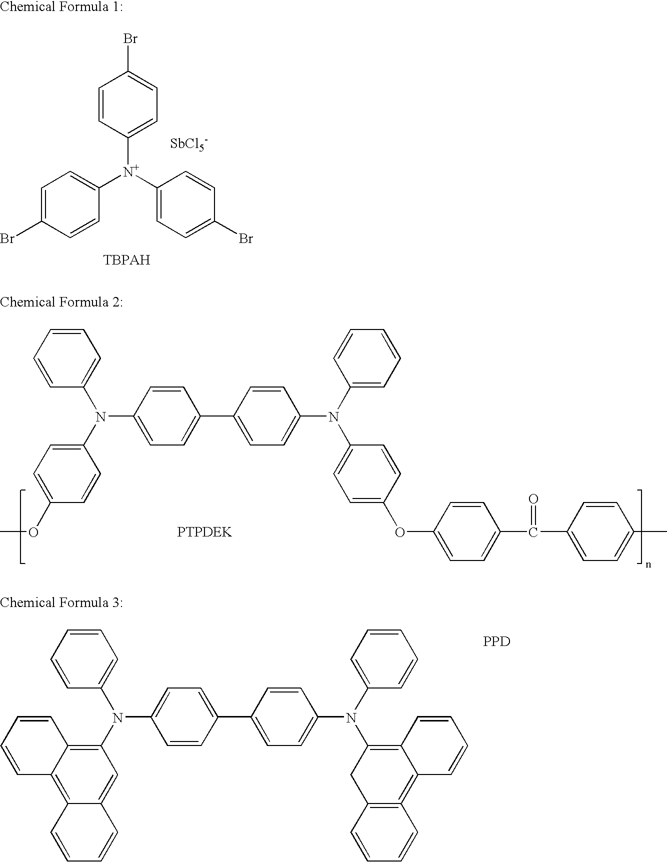

In this case, although display non-uniformity did not become prominent according to the film thickness distribution of the layer of PTPDEK, the luminance lifetime was short. One of the causes is supposed to be that TPBAH has high moisture absorption. While the ionization potential of TPBAH is as high as 9.6×10⁻⁹ J (6 eV), the moisture absorption of TPBAH is high. It is supposed that the excited state of Alq₃ is quenched since the applied film contains much residual moisture.

Next, a similar organic EL element was fabricated, changing the dopants from the above-stated TBPAH to sulfosalicylic acid, which has low moisture absorption, in order to reduce the amount of residual moisture in the applied film. The degradation in the luminance lifetime of the element was measured, and it was revealed that the luminance lifetime was improved in comparison with the element using TBPAH.

However, it was acknowledged that this element using sulfosalicylic acid was subjected to chrominance non-uniformity according to the thickness distribution of the applied film. Additionally, it was revealed that the driving voltage of this element increased in comparison with the above-stated element using TPBAH as dopants. The chrominance non-uniformity was caused so that a portion where the applied film was thick was dark while a portion where the applied film was thin was light. From this point of view, it is estimated that chrominance non-uniformity became visible since the resistance of the film disposed by the application method was highlighted for some reason.

As explained above, it is expected to increase interlayer short-circuit endurance by the application method.

On the other hand, when dopants having high oxidizability are used to reduce the driving voltage of an organic EL element, a non-emissive area is formed, or the luminance lifetime is deteriorated by an adverse effect caused by moisture contained in the element. Conversely, when dopants having low oxidizability is used, display non-uniformity becomes prominent according to the thickness distribution, though the formation of a non-emissive area or a degradation in the luminance lifetime is suppressed.

The present invention is proposed under the circumstances stated above. It is an object to improve the interlayer short-circuit endurance of an organic EL element, to restrain a non-emissive area from being formed or luminance lifetime from being deteriorated, to reduce the driving voltage and to suppress display non-uniformity.

The inventors have been dedicated to making research and development, and have found that the above-stated chrominance non-uniformity can be avoided by a combination of an organic material used for organic multi-layer thin films, dopants and an organic material disposed on the organic multi-layer thin films. The inventors have also found that it is possible to reduce the driving voltage of an organic EL element and to obtain an organic EL element having interlayer short-circuit endurance.

According to a first aspect of the present invention, there is provided an organic EL element comprising an anode, a cathode, and an organic EL layer disposed between the anode and the cathode; the organic EL layer comprising a first organic thin film in contact with the anode, and a second organic thin film in contact with the first organic thin film; the first organic thin film including organic-thin-film-forming-molecules and dopants oxidizing the organic-thin-film-forming-molecules, the dopants having a reduction potential of 0.5 to 0.85 V with respect to a standard hydrogen electrode; and the second organic thin film having an ionization potential of 8.5×10⁻¹⁹ J or below. Molecules in the interface of the second organic thin film with the first organic thin film can be oxidized even by low oxidizability dopants to lower the energy barrier between the first organic thin film and the second organic thin film since the use of such low oxidizability dopants restrains an adverse effect from being caused by moisture in the organic EL element and since the second organic thin film comprises a material having a low ionization potential.

According to a second aspect of the present invention, the ionization potential of the organic-thin-film-forming-molecules of the first organic thin film is lower than that of the second organic thin film by 3.2×10⁻²⁰ J or above in the organic EL element recited in the first aspect. By this arrangement, it is possible to significantly improve the injection ability of holes from the anode.

According to a third aspect of the present invention, the first organic thin film has a career concentration of 5×10¹⁸ (1/cm³) or above in the organic EL element recited in the first or the second aspect. By having such a career concentration, it is possible to sufficiently lower the energy barrier between the first organic thin film and the second organic thin film the energy barrier and to greatly offer effects of suppressing chrominance non-uniformity and of reducing the driving voltage.

According to a fourth aspect of the present invention, the organic-thin-film-forming-molecules of the first organic thin film are water-insoluble in the organic EL element recited in the first to the third aspect. By this arrangement, it is possible to suppress the amount of moisture contained in a thin film.

According to a fifth aspect of the present invention, the organic-thin-film-forming-molecules of the first organic thin film have a molecular weight of 1,000 or above in the organic EL element recited in the first to the fourth aspect. By this arrangement, it is possible to suppress non-uniformity in a film thickness and to improve coatability with respect to unevenness of the anode.

According to a sixth aspect of the present invention, the dopants of the first organic thin film comprise organic acid in the organic EL element recited in any one of the first to the fifth aspect. Organic acid is effective as low moisture absorption dopants. According to a seventh aspect of the present invention, the dopants of the first organic thin film comprise a benzenesulfonic acid derivative in the organic EL element recited in the sixth aspect. Such a sulfonic acid derivative is a preferred material because of having both properties of oxidizability and low moisture absorption.

According to an eighth aspect of the present invention, the dopants in the first organic thin film have a molecular weight of 10,000 or below in the organic EL element recited in any one of the first to the seventh aspect. By using such dopants, it is possible to greatly expand the selection range of the solvent.

According to a ninth aspect of the present invention, the first organic thin film comprises a thin film, which is disposed by applying a liquid containing the organic-thin-film-forming-molecules and the dopants in the [symbol] organic EL element recited any one of the first to the eighth aspect. According to a tenth aspect of the present invention, there is provided an organic EL display device comprising a plurality of organic EL elements recited in any one of the first to the ninth aspect.

According to an eleventh aspect of the present invention, there is provided a method for fabricating an organic EL element, comprising disposing an anode on a substrate, disposing an organic EL layer in contact with the anode, and disposing a cathode in contact with the organic EL layer; the step for disposing the organic EL layer comprising applying a liquid on the anode to dispose a first organic thin film in contact with the anode, the liquid containing organic-thin-film-forming-molecules and dopants oxidizing the organic-thin-film-forming-molecules; and disposing a second organic thin film in contact with the first organic thin film; the dopants in the first organic thin film having a reduction potential of 0.5 to 0.85 V with respect to a standard hydrogen electrode; and the second organic thin film having an ionization potential of 8.5×10⁻¹⁹ J or below.

In accordance with the present invention, it is possible to obtain an organic EL element, which combines high display quality, a low driving voltage and interlayer short-circuit endurance.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of the organic EL element according an embodiment of the present invention;

FIG. 2 is a schematic top plan view of an typical example of a substrate with the organic EL display panel according to this embodiment;

FIG. 3 is a cross-sectional view of a portion of the organic EL display panel taken along line A-A of FIG. 2;

FIG. 4 is a flowchart showing a method for fabricating the organic EL display panel according to this embodiment; and

FIG. 5 is a flowchart showing a method for fabricating the organic EL layer according to this embodiment.

Now, an embodiment, to which the present invention is applicable, will be described. The following description is provided for explanation of the embodiment of the present invention, and the present invention is not limited to the embodiment described below.

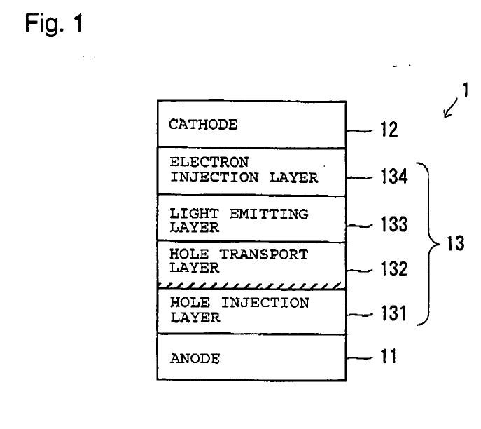

FIG. 1 is a schematic cross-sectional view showing an typical example of the structure of the organic EL (Electroluminescence) element of this embodiment. The organic EL element 1 has a laminated structure, which comprises an anode 11, a cathode 12 disposed to confront the anode 11, and an organic EL layer 13 disposed between the anode 11 and the cathode 12. The anode 11 comprises a transparent conductive film made of ITO or the like. The cathode 12 comprises a metal material, such as aluminum.

The organic EL layer 13 has a multilayered structure, which comprises a plurality of laminated thin films. In the typical example shown in FIG. 1, the organic EL layer 13 has a four-layered structure, which comprises a hole injection layer 131, a hole transport layer 132, a light emitting layer 133 and an electron injection layer 134 sequentially laminated in this order from a side of the anode 11. The hole injection layer 131 is one example of a first organic thin film in contact with the anode 11, and the hole transport layer 132 is one example of a second organic film in contact with the first organic thin film.

The hole injection layer 131 comprises an organic thin film, which may be disposed on the anode 11 by an application method, such as a spray method. The application method is a technique wherein an organic material is dispersed or dissolved in a liquid, and the organic material is applied to dispose a desired organic thin film. The application method can be utilized to cover a foreign material, a projection, a recess or the like on the anode 11, thereby to avoid the formation of interlayer short-circuit in the organic EL element. Other application methods than the spray method are also applicable.

The organic material that is usable in the application method is broadly classified into a water-soluble (or water-dispersible) one and a water-insoluble one that can dissolve in an organic solvent. When the hole injection layer 131 comprises a water-soluble organic material, the amount of moisture, which is brought into the organic thin film, increases, easily causing adverse effects, such as luminance degradation. For this reason, it is preferred that the organic material for the hole injection layer 131 be water-insoluble. Thus, the amount of moisture contained in the organic thin film can be suppressed, restraining the formation of a non-emissive area or luminance degradation caused by moisture in the organic EL element 1.

It is also preferred that the organic-thin-film-forming-molecules of the hole injection layer 131 be polymers having a molecular weight of 1,000 or above. When the hole injection layer 131 is disposed by the application method, it is possible to use an organic material having a small molecular weight. However, by using an organic material having the above-stated molecular weight, the occurrence of non-uniformity in the is film thickness can be minimized, having excellent coatability with respect to unevenness of the anode 11 and more effectively avoiding the generation of interlayer short-circuit.

Although it is typical that the hole transport layer 132 and its subsequent layers are disposed by vacuum deposition, these layers may be disposed by the application method if properly designed. The electron injection layer 134 may comprise, e.g., LiF. An electron transport layer may be disposed between the light emitting layer 133 and the electron injection layer 134, being independent from the light emitting layer 133. There is no particular limitation to the material of the light emitting layer 133. The light emitting layer may comprise, e.g., tris(8-quinolinolate)aluminum (Alq₃) and coumarin 6 serving as the fluorescent pigment of a guest compound.

Now, the hole injection layer 131 and the hole transport layer 132 will be described in detail. The hole injection layer 131 lowers the injection barrier of holes from the anode 11 to reduce the driving voltage. The hole injection layer 131 according to this embodiment contains organic-thin-film-forming-molecules, and dopants for oxidizing such molecules. The dopants oxidize some of the organic-thin-film-forming-molecules to chemically create holes, thereby improving the conductivity of the hole injection layer 131.

In this embodiment, the dopants in the hole injection layer 131 are controlled to have a reduction potential set at 0.5 to 0.85 V with respect to a standard hydrogen electrode. Additionally, The hole transport layer 132, which transports holes to the light emitting layer 133, is controlled to have an ionization potential of 8.5×10⁻¹⁹ J (5.3 eV) or below. The dopants have higher moisture absorption as their oxidizability becomes higher. When the reduction potential, which is an index showing the oxidizability of the dopants, is set at 0.85 V or below, the amount of the moisture that is caused to remain in the hole injection layer 131 by the moisture absorption of the dopants can be decreased, effectively suppress the formation of a non-emissive area and luminance degradation in the organic EL element 1.

Some of the dopants, which are contained in the hole injection layer 131, exist in the interface with the hole transport layer 132 in contact with the hole injection layer. When hole transporting materials are oxidized by dopants, holes are created in the interface of the hole transport layer 132 close to the hole injection layer 131.

The holes thus created lower the energy barrier between the hole injection layer 131 and the hole transport layer 132, with the result that variations in element resistance caused by variations in the film thickness of the hole injection layer 131 can be reduced. Simultaneously, the carrier concentration in the hole transport layer 132 can also increase to decrease the resistance of the entire organic EL element to a lower level. However, when the dopants have lower oxidizability, the dopants cannot oxidize hole transporting materials in a sufficient way, with the result that display non-uniformity, which is caused by variations in the element resistance caused by variations in the film thickness of the hole injection layer 131, can be generated.

As explained above, in the organic EL element 1 according to this embodiment, the reduction potential of the dopants in the hole injection layer 131 as the first organic thin film is controlled to be set at 0.5 V or above, and the ionization potential of the hole transport layer 132 is controlled to be set at 8.5×10⁻¹⁹ J (5.3 eV) or below. By this arrangement, molecules in the interface of the hole transport layer 132 with the hole injection layer 131 are oxidized even by dopants having low oxidization, with the result that the energy barrier between the hole injection layer 131 and the hole transport layer 132 can be lowered. Thus, in despite of using dopants having low oxidization, resistance variations in the interface of the hole transport layer 132 can be reduced, minimizing the generation of display non-uniformity, which is caused if there are resistance variations in the interface of the hole transport layer.

As the dopants have a lower reduction potential (lower oxidizability), the moisture absorption of the hole injection layer is lower. However, when the oxidizability of the dopants is too low, organic molecules, which exist in the hole injection layer and in the interface of the hole transport layer with the hole injection layer, cannot be oxidized. From this point of view, the reduction potential of the dopants is preferably 0.6 to 0.85 V with respect to the standard hydrogen electrode, more preferably 0.6 to 0.75 V with respect to the standard hydrogen electrode.

The dopants in the hole injection layer 131 preferably comprise organic acid having low moisture absorption in order to suppress the adverse effect caused by moisture in the organic EL element 1. As the organic acid, a sulfonic acid derivative is a particularly preferred dopant material since this derivative is excellent in terms of having balanced properties of oxidizability and moisture absorption. As the dopants have a smaller molecular weight, the selection range of the solvent can be wider. From this point of view, the molecular weight of the dopants in the hole injection layer is preferably 10,000 or below, more preferably 1,000 or below.

It is preferred that the ionization potential of the organic-thin-film-forming-molecules in the hole injection layer 131 be lower than the ionization potential of the hole transport layer 132 by 3.2×10⁻²⁰ J (0.2 eV) or is above. By lowering the ionization potential in the hole injection layer 131 to such a level, it is possible to significantly improve the injection ability of holes from the anode 11. When the ionization potential in the hole injection layer 131 is lowered, the energy barrier between the hole transport layer 132 and the hole injection layer is generally raised. However, in this embodiment, dopants contained in the hole injection layer 131 oxidize molecules in the interface of the hole transport layer 132 with the hole injection layer (see the hatched portion in FIG. 1), causing the energy barrier to lower. Accordingly, it is possible to improve the injection ability of holes in the hole injection layer 131 and the hole transport layer 132 in their entireties.

It is preferred that the carrier concentration in the hole injection layer 131 be 5×10¹⁸ (1/cm³) or above. When-the carrier concentration is set at 5×10¹⁸ (1/cm³) or above, the energy barrier between the hole injection layer 131 and the hole transport layer 132 can be lowered in a sufficient way, more effectively exhibiting the effects of suppressing display non-uniformity and of reducing the driving voltage.

As explained above, by disposing the hole injection layer 131 in contact with the anode 11 by use of the application method, it is possible to improve the interlayer short-circuit endurance. By causing the hole injection layer 131 to contain dopants having lower oxidizability, it is possible not only to reduce the driving voltage but also to restrain the display quality of the organic EL element from being lowered by residual moisture. By selecting organic-thin-film-forming-molecules having a low ionization potential as the hole transporting material disposed on the hole injection layer 131, it is possible to minimize the occurrence of resistance variations in the interface of the hole transport layer 132 and to restrain display non-uniformity from being caused by the resistance variations, in spite of using dopants having low oxidizability. Although explanation has been made about a case wherein the organic EL layer 13 has a four-layered structure, the organic EL element according to the present invention is not limited to have such a structure.

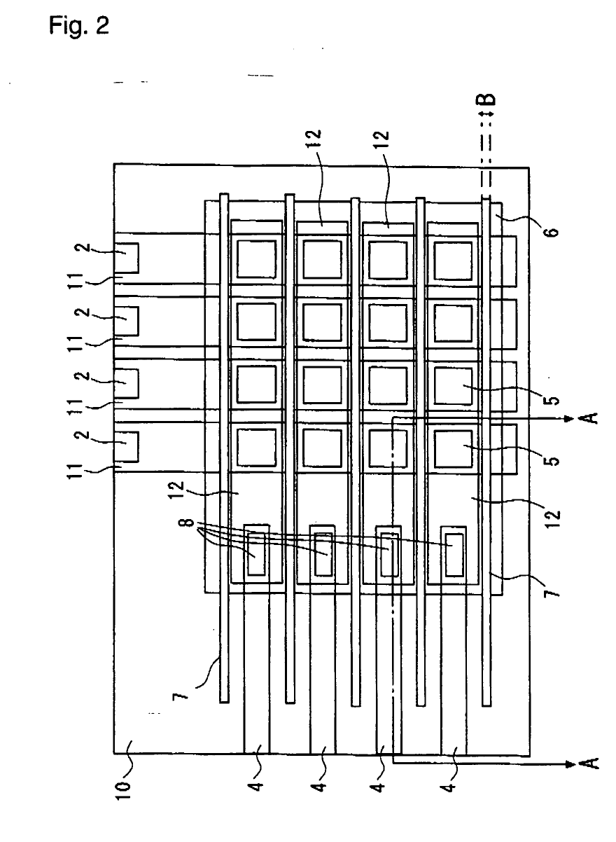

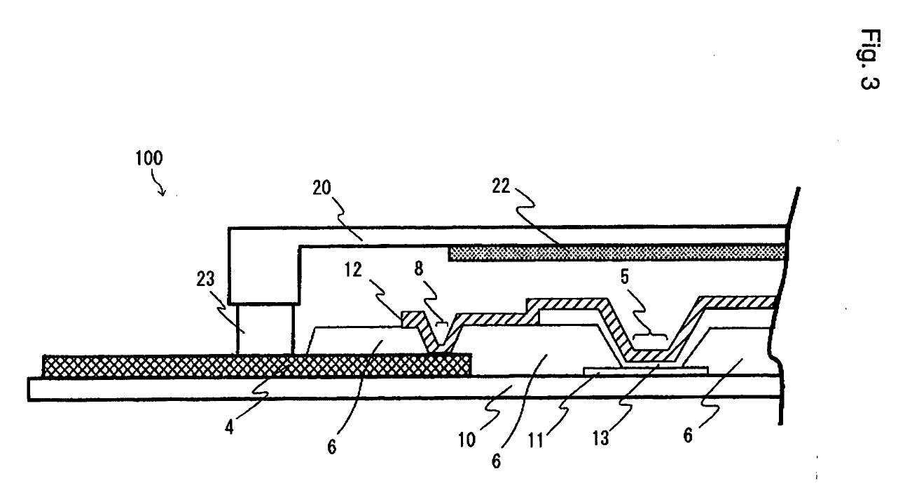

Now, an organic EL display panel using an organic EL element 1 according to the present invention will be described, referring to FIGS. 2 and 3. FIG. 2 is a schematic top plan view showing the structure of an element substrate with the organic EL element disposed thereon in the organic EL display panel 100 according to this embodiment. FIG. 3 is a partial cross-sectional view of the organic EL display panel l 00 taken along line A-A of FIG. 2. As shown in FIG. 2, the organic EL display panel l 00 according to this embodiment includes anode wires corresponding to anodes 11 (hereinbelow, referred to as the anode wires 11), anode supplemental wires 2, cathode wires corresponding to cathodes 12 (hereinbelow, referred to as the cathode wires 12), cathode supplemental wires 4, an insulating film 6, openings 5 formed in the insulating film, cathode separators 7, contact holes 8 and the substrate 10. As shown in FIG. 3, the organic EL display panel 100 also includes an organic EL layer 13, a desiccant 22, a counter substrate 20 and a seal for encapsulation 23.

The substrate 10 may comprise a non-alkali glass substrate (e.g. a product commercially available under the product name “AN100” manufactured by Asahi Glass Company, Limited) or an alkali glass substrate (e.g. a product commercially available under the product name “AS” manufactured by Asahi Glass Company, Limited). Although there is no limitation to the thickness of the substrate 10, it is preferred to use a substrate having a thickness of, e.g., 0.7 to 1.1 mm.

The substrate 10 has the plural anode wires 11 disposed thereon so as to extend in parallel to one another as shown in FIG. 2. It is preferred that the anode wires 11 comprise, e.g. ITO. The anode supplemental wires 2 are electrically connected to the anode wires 11 at edge portions of the anode wires 11, respectively. The anode supplemental wires are disposed so as to extend from connection portion with the anode wires 11 toward an edge portion of the substrate. In is other words, the anode supplemental wires are disposed in the same number as the anode wires 11. The anode supplemental wires are disposed so as to extend in parallel to one another as in the anode wires 11.

Each of the anode supplemental wires 2 serves as a metal pad for connection with an external wire, such as an FPC (Flexible Printed Circuit board) or a TCP (Tape Career Package), through an anisotropic conductive film (hereinbelow, referred as “ACF”) on a portion close to the edge portion of the substrate 10. By this arrangement, current is supplied to the anode wires 11 through the anode supplemental wires 2 from a driving circuit externally disposed.

The substrate also has the plural cathode wires 12 disposed thereon so as to extend in-parallel to one another and perpendicular to the anode wires 11 as shown in FIG. 2. The cathode wires 12 normally comprise Al or an Al alloy. The cathode wires may comprise alkali metal, such as Li, Ag, Ca, Mg, Y, In or an alloy containing at least one of them. The cathode wires may also comprise a transparent conductive film. The cathode wires are set so as to have a thickness of about 50 to about 300 nm.

The cathode supplemental wires 4 are electrically connected to the cathode wires 12 through the contact holes 8 at edge portions of the cathode wires 12, respectively. The cathode supplemental wires are disposed so as to extend from the edge portions of the cathode wires 12 toward an edge portion of the substrate. In other words, the cathode supplemental wires are disposed in the same number as the cathode wires 12. The cathode supplemental wires are disposed so as to extend in parallel to one another as in the cathode wires 12. Each of the cathode supplemental wires 4 serves as a metal pad for connection with an external wire, such as an FPC or a TCP, on a portion close to the edge portion of the substrate 10 with the cathode supplemental wires disposed thereon, as in the anode supplemental wires 2. The contact hole may be formed so as to have dimensions of, e.g., 200 μm×200 μm.

The above-stated cathode supplemental wires 4 and the above-stated anode supplemental wires 2 may comprise a metal film having-a multilayered structure or a monolayered structure. For example, both supplemental wires may have a multilayered structure wherein a Mo/Nb layer, an Al layer and a Mo/Nb layer are laminated in this order from a side of the substrate 10.

The insulating film 6 with the openings is disposed on the anode wires 11, the anode supplemental wires 2 and the cathode supplemental wires 4 so as to partly cover these wires (see FIG. 2 and FIG. 3). Each opening 5 for a pixel is located at a position where an anode wire 11 and a cathode wire 12 intersect each other as viewed in a plan view. Each opening 5 for a pixel corresponds to a pixel area. For example, the insulating film 6 with the openings may have a film thickness of 0.7 μm, and each opening 5 for a pixel may have dimensions of 300 μm×300 μm.

The organic EL layer 13 is disposed on the anode wires 11 and the insulating film 6 with the openings and is configured so as to be sandwiched between the anode wires 11 and the cathode wires 12 as shown in FIG. 3. The organic EL layer 13 normally has a thickness of about 100 to about 300 nm. The organic EL layer 13 is disposed so as to meet the conditions explained in reference to FIG. 1. For example, the organic EL layer 13 comprises the hole injection layer 131, the hole transport layer 132, the light emitting layer 133 and the electron injection layer 134 as shown in FIG. 1. The hole injection layer 131 contains organic-thin-film-forming-molecules and dopants. The reduction potential of the dopants and the ionization potential meet the conditions explained in reference to FIG. 1

The cathode separators 7 are disposed so as to extend parallel to the cathode wires 12 as shown in FIG. 2. The cathode separators 7 play a role to spatially separate the plural cathode wires 12 from one another in order to prevent the cathode wires 12 from being connected together. It is preferred that the cathode separators 7 have an inverted tapered shape in section. The inverted tapered shape means that the cross-sectional shape of the separators (the cross-sectional shape seen from a direction of B in FIG. 2) has wider cross-sectional widths (in the direction of B in FIG. 2) as the distance from the substrate 10 increases. By this arrangement, it is possible to spatially separate the plural cathode wires 12 in an easy way in the step for disposing the cathode wires 12 stated later since the sidewalls and the rising portions of the cathode separators 7 are located in the shade. The cathode separators 7 may have dimensions of 3.4 μm in height×10 μm in width, for example.

The above-stated substrate 10 is bonded to the counter substrate 20 through the seal 23 to encapsulate a space with the organic EL layer 13 and the like disposed therein. Encapsulation is performed in order to prevent the organic EL layer 13 from being deteriorated by moisture in the air. The counter substrate 20 may comprise a glass substrate having a thickness of 0.7 to 1.1 mm, for example. The counter substrate may comprise the same material as the substrate 10. The counter substrate 20 has the desiccant 22 disposed thereon so as to have a gap with the organic EL layer 13, the cathode wires 12 and the like In other words, the desiccant 22 is disposed so as to be apart from the organic EL element 1 including the anode wires 11, the organic EL layer 13 and the cathode wires 12.

The desiccant 22 may comprise a viscous moisture-absorbing material having a certain viscosity, for example. Or, the desiccant may comprise an organic metal compound, which is highly reactive with moisture and is formed in a film shape. The desiccant may also comprise an inorganic desiccant. When the desiccant 22 comprises a viscous moisture-absorbing material, the viscous moisture-absorbing material may be prepared by mixing a certain amount of absorbent in an inactive liquid comprising fluorinated oil. Or, the viscous moisture-absorbing material may be prepared by mixing a certain amount of absorbent in an inactive gel material, such as a fluorinated gel.

The absorbent may comprise a material capable of physically or chemically absorbing moisture, such as activated alumina, molecular sieves, calcium oxide and barium oxide. The viscous moisture-absorbing material is prepared so as to have such a creamy or gel viscosity to prevent the absorbent from freely flowing, and the viscous moisture-absorbing material thus prepared is applied and disposed at a certain position.

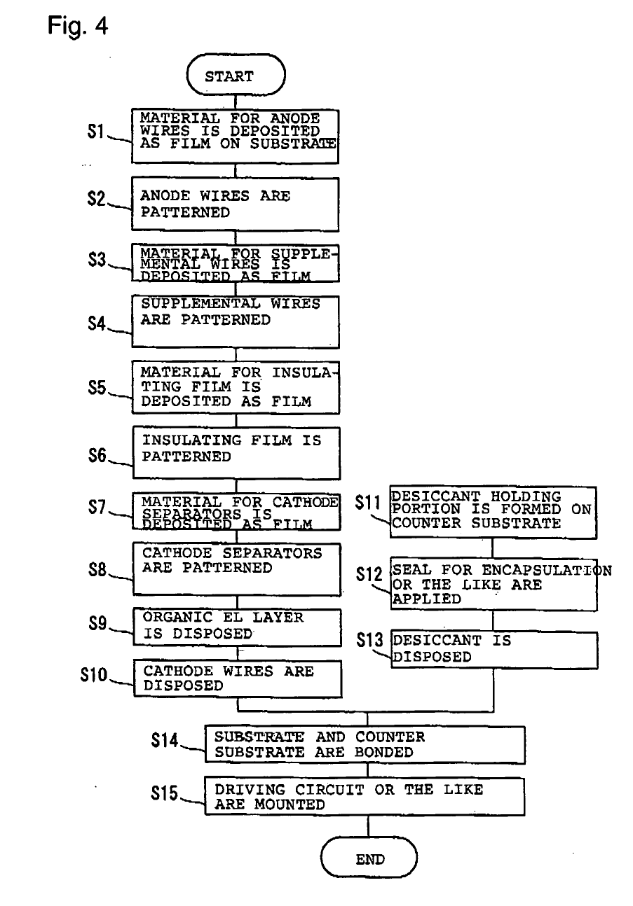

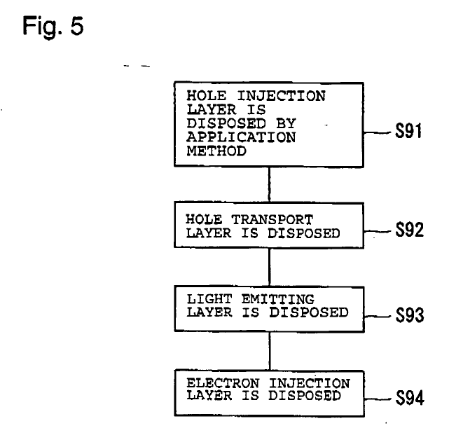

A method for fabricating the organic EL display according to the present invention will be described, referring to FIGS. 4 and 5. The method described below is a typical example in the case of the organic EL display. It should be noted that other methods are applicable as long as they do not depart from the spirit of the invention. FIG. 4 is a flowchart showing a fabrication process for the organic EL display according to this embodiment.

In FIG. 4, a material for the anode wires is deposited as a film on the substrate 10 in Step S1. The material for the anode wires, which comprises, e.g., ITO, is uniformly deposited as a film on the entire surface of the substrate by, e.g., sputtering or vapor deposition.

Next, the deposited material for the anode wires is patterned to form the anode wires 11 by a photolithographic step and an etching step in Step S 2. The etching step may be performed by either a wet-etching method or a dry etching method. For example, the etching step is performed, using a phenol novolak resin as a resist, by the wet-etching method. A solution with hydrochloric acid and nitric acid mixed therein is used as a processing liquid, and a solution with monoethanolamine and dimethylsulfoxide mixed therein is used as a stripping liquid.

Next, a material for the supplemental wires is deposited as a film on the anode wires by sputtering or vapor deposition in Step S3. The material for the supplemental wires may comprise, e.g., a metal material having a low resistance, such as Al or an Al alloy. From the viewpoint of, e.g., improving adhesion with an underneath layer and of preventing corrosion, the supplemental wires may formed in a multilayered structure by disposing a barrier layer made of TiN, Cr, Mo or the like as a upper or lower layer made of an Al film. For example, the supplemental wire may be formed in a multilayered structure of Mo/Al/Mo having a total thickness of 450 nm by a DC sputtering method.

Next, the material for the supplemental wires deposited in the above-stated Step S3 is patterned to form the anode supplemental wires 2 and the cathode supplemental wires 4 by a photolithographic step and an etching step in Step S4. For example, wet-etching is performed, using an etching solution with phosphoric acid, acetic acid and nitric acid mixed therein. The materials for the supplemental wires and the material for the cathode wires may be sequentially patterned after the material for the anodes and the material for the supplemental wires have been sequentially deposited as films.

After that, a material for the insulating film, such as photosensitive polyimide, is deposited as a film by, e.g., spin-coating in Step S5.

Next, the insulating film is patterned in Step S6. Patterning is carried out so that the openings 5 for the respective pixels serving an active area and the contact holes 8 are formed in the insulating film. When photosensitive polyimide is used, the insulating film 6 is patterned so as to have the openings 5 and the contact holes 8 formed therein as shown in FIG. 2 and FIG. 3 by performing a curing step after having performed an exposure step and a development step.

Next, a material for the cathode separators is deposited as a film in Step S7. For example, a photosensitive novolac resin, a photosensitive acrylic resin or the like is deposited as a film by spin-coating.

After that, the material for the cathode separators is patterned in Step S8. By patterning, each of the cathode separators 7 is disposed in a gap to be located between adjacent cathode wires 17 so as to extend parallel with the cathode wires 12 as shown in FIG. 2. It is preferred that the cathode separators 7 have an inverted tapered shape in section (the cross-sectional shape seen from the B direction in FIG. 2). When a negative photosensitive resin is used, it is easy to form such an inverted tapered structure in the exposure step since the cathode separators 7 have a lower portion subjected to more insufficient photoreaction.

It should be noted that in order to provide surface modification to portions of the ITO film exposed from the openings 5 formed in the insulating film, a step for irradiating oxygen plasma or ultraviolet may be inserted before Step S 9 stated later.

Subsequently, the organic EL layer 13 is disposed in Step S9. Referring now to FIG. 5, the hole injection layer 131 is disposed as the lowest layer by use of an application method in Step S91. For example, the hole injection layer 131 is disposed by a spray method. The hole injection layer 131 may be disposed by using a solution with PTPDEK (5 mg/ml) and para-toluenesulfonic acid (20 wt %) dissolved in cyclohexanone, for example. Next, the solution is condensed and dried to be cured, disposing the hole injection layer 131.

Subsequently, the other organic layers forming the organic EL layer 13 are disposed as upper layers of the hole injection layer 131 in Step S92. For example, the hole transport layer 132 is disposed so as to have a film thickness of 50 nm by 2-TNATA (represented by Chemical Formula 4). Additionally, Alq(tris(8-hydroxyquinolinato)aluminum as the host compound of the light emitting layer 133 and coumarin 6 as the fluorescent pigment of the guest compound are simultaneously formed by vapor deposition to dispose the light emitting layer 133 (also serving as the electron transport layer) having a film thickness of 60 nm in Step 93. Subsequently, the electron injection layer 134 is disposed so as to have a film thickness of 0.5 nm by forming e.g., Lif as an upper layer of the light emitting layer 133 by vapor deposition in Step S94.

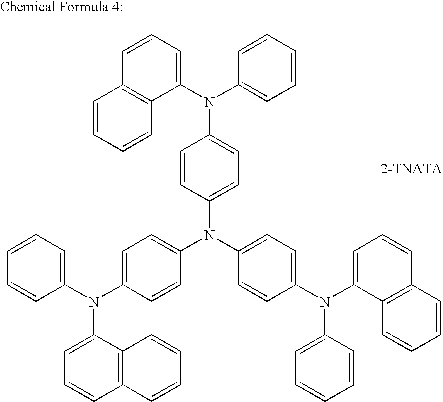

Referring back to FIG. 4, a material for the cathode wires, which is used for disposing the cathode wires, is accumulated by e.g., mask vapor deposition in Step S10.

Next, a step for preparing the counter substrate, which encapsulates the organic EL element 1, will be is described.

First, a desiccant housing portion is formed so as to have a concave shape on the counter substrate 20 by, e.g., etching or sandblast in Step S11.

Subsequently, the seal for encapsulation 23, which are made of, e.g., a photo cationic polymerizable epoxy resin, is applied on the surface of the counter substrate with the concave housing portion in Step S 12. The cathode supplemental wires 4 and the anode supplemental wires 2 are disposed so as to extend to outside the seal for encapsulation 23 in order to be connected to a driving circuit externally provided as stated later. After that, the desiccant 22 is disposed in Step S13.

After that, the substrate 10 and the counter substrate 20 are bonded together in Step S14. Specifically, the substrate 10 and the counter substrate 20 are aligned with each other, followed by applying a pressure to both substrates and irradiating the respective seals with UV light. Thus, the substrate 10 with the organic EL element disposed thereon, and the counter substrate 20 are bonded together. As a result, the organic EL element 1 is encapsulated.

Finally, the driving circuit and the like are mounted in Step S 51. Edge portions of the cathode supplemental wires 4 and the anode supplemental wires 2, which extend to outside the seal for encapsulation 23, are bonded to the ACF and are connected to the TCP with the driving circuit disposed thereon. Then, the organic EL display panel 100 is mounted to a casing, completing the fabrication of an organic EL display.

Now, the embodiment will be more specifically described, referring to examples. The examples are not intended to narrowly construe the present invention.

### EXAMPLE 1

Example 1 will be explained, referring to Table 1. The organic EL element was fabricated so as to have a laminated structure, which comprised anodes, a first organic thin film (hole injection layer), a second organic thin film (hole transport layer), a third organic thin film (light emitting layer), a fourth thin film (electron injection layer) and cathodes. The anodes were made of an ITO film having 150 nm. The first organic thin film (hole injection layer) was disposed, using a solution containing PTPDEK (5 mg/ml) and para-toluenesulfonic acid (20 wt*) as the dopants dissolved therein, by a spray method. Cyclohexanone was used as the solvent. The second organic thin film (hole transport layer) was made from 2-TNATA having a film thickness of 50 nm. The third organic thin film (light emitting layer), and the fourth thin film (electron injection layer) were made from Alq₃ having a film thickness of 60 nm and from Lif having a film thickness of 0.5 nm, respectively. The cathodes were made of an Al film having 80 nm.

The reduction potential of para-toluenesulfonic acid of the first organic thin film is 0.75 V with respect to the standard hydrogen electrode, and the ionization potential of 2-TNATA of the second organic thin film is 8.2×10⁻¹⁹ J (5.1 eV) . And, the ionization potential of PTPDEK as the organic-thin-film-forming-molecules is 8.6×10⁻¹⁹ J (5.4 eV).

In the case of the element structure stated above, any non-emissive area deriving from chrominance non-uniformity or moisture, which reflected the film thickness distribution of an applied film, was not recognized. The mobility found by mobility measurement (TOF method) was 10⁻⁷ cm²/Vs.

Based on the current-voltage characteristics of the element having a structure of ITO/first-organic-thin-film (10 nm)/Al and on the mobility found as stated above, it was estimated that the career concentration was about 5×10¹⁸ (1/cm³). Based on this value, it is estimated that 2-TNATA was oxidized in the interface between PTPDEK of 2-TNATA and the dopant layer of para-toluenesulfonic acid, thereby suppressing chrominance non-uniformity in this element.

In addition, with regard to the driving voltage, the voltage capable of obtaining current of 500 mA/cm² decreased by about 2 V, in comparison with a case of using PPD having an ionization potential of 8.6×10⁻¹⁹ J (5.4 eV) as the hole transporting material.

TABLE 1

| | |
|---|---|
| first organic thin film | |
| forming-molecules | PTPDE |
| | molecular weight (15,000 to |
| | 25,000) |
| dopants | para-toluenesulfonic acid |
| reduction potential of | 0.75 V |
| dopants | |
| ionization potential of | 8.6 × 10⁻¹⁹ J (5.4 eV) |
| forming-molecules | |
| career concentration | 5 × 10¹⁸ (l/cm³) |
| second organic thin film | |
| forming-molecules | 2-TNATA |
| ionization potential | 8.2 × 10⁻¹⁹ J |

### EXAMPLE 2

In Example 2, the organic EL element was fabricated so as to have a laminated structure, which comprised anodes, a first organic thin film (hole injection layer), a second organic thin film (hole transport layer), a third organic thin film (light emitting layer), a fourth thin film (electron injection layer) and cathodes. The anodes were made of an ITO film having 150 nm. When the first organic thin film (hole injection layer) is disposed, 150 wt % of sulfosalicylic acid as the dopants was first added to oligoaniline units represented by Chemical Formula A and tetracarboxylic dianhydride, the mixture was dissolved in a solution of cyclohexanone, and the solution was applied as an applied film by a spray method. After that, the applied film was baked at 250° C. for one hour to obtain organic-thin-film-forming molecules represented by Chemical Formula B.

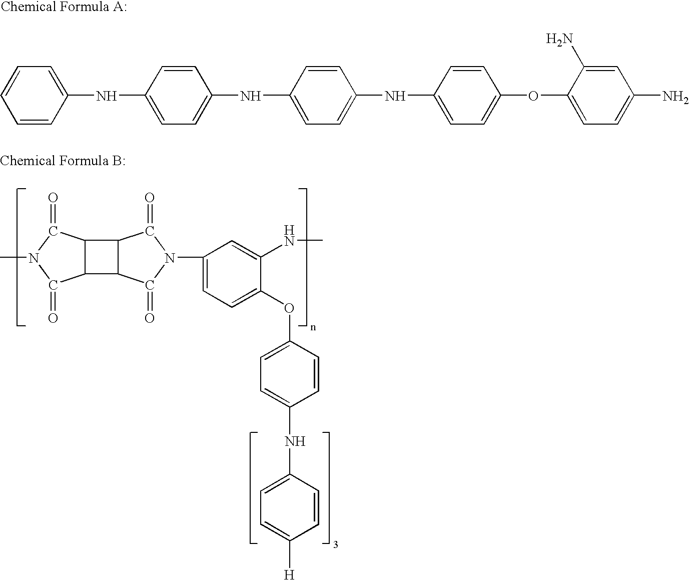

The second organic thin film (hole transport layer) was made from HI406 (manufactured by Idemitsu Kosan Co., Ltd.), having a film thickness of 50 nm. The third organic thin film (light emitting layer) and the fourth thin film (electron injection layer) were made from Alq₃ having a film thickness of 60 nm and from Lif having a film thickness of 0.5 nm, respectively. The cathodes were made of an Al film having 80 nm.

As shown in Table 2, the reduction potential of sulfosalicylic acid of the first organic thin film is 0.75 V with respect to the standard hydrogen electrode, and the ionization potential of HI406 of the second organic thin film is 8.4×10⁻¹⁹ J (5.2 eV). And, the ionization potential of the organic-thin-film-forming-molecules represented by Chemical Formula 2 is 8.2×10⁻⁹ J (5.1 eV).

In the case of the element structure stated above, any non-emissive area deriving from chrominance non-uniformity or moisture, which reflected the film thickness distribution of an applied film, was not recognized. The mobility found by mobility measurement (TOP method) was 10⁻⁷ cm²/Vs.

Based on the current-voltage characteristics of the element having a structure of ITO/first-organic-thin-film (10 nm)/Al and on the mobility found as stated above, it was estimated that the career concentration was about 2×10¹⁹ (1/cm³). Based on this value, it is estimated that HI406 was oxidized in the interface of H 1406 with the first organic thin film, thereby suppressing chrominance non-uniformity in this element.

In addition, with regard to the driving voltage, the voltage capable of obtaining current of 500 mA/cm² decreased by about 3 V, in comparison with a case of using PPD having an ionization potential of 8.6×10⁻¹⁹ J (5.4 eV) as the hole transporting material. The reason is supposed to be that the injection ability of holes to the light emitting layer has been improved since the ionization potential of HI406 as the hole transporting material was larger than 2-TNATA by 1.6×10⁻²⁰ J (0.1 eV).

TABLE 2

| | |
|---|---|
| first organic thin film | |
| forming molecules | Chemical Formula B |
| | molecular weight (about |
| | 1,050) |
| dopants | sulfosalicylic acid |
| reduction potential of | 0.75 V |
| dopants | |
| ionization potential of | 8.2 × 10⁻¹⁹ J |
| forming-molecules | |
| career concentration | 2 × 10¹⁹ (l/cm³) |
| second organic thin film | |
| forming-molecules | HI406 |
| ionization potential | 8.4 × 10⁻¹⁹ J (5.2 eV) |

The entire disclosure of Japanese Patent Application No. 2005-019015 filed on Jan. 27, 2005 including specification, claims, drawings and summary is incorporated herein by reference in its entirety.

What is claimed is:

1. An organic EL element comprising:
an anode, a cathode, and an organic EL layer disposed between the anode and the cathode;
the organic EL layer comprising a first organic thin film in contact with the anode, and a second organic thin film in contact with the first organic thin film;
the first organic thin film including organic-thin-film-forming-molecules and dopants oxidizing the organic-thin-film-forming-molecules, the dopants having a reduction potential of 0.5 to 0.85 V with respect to a standard hydrogen electrode; and
the second organic thin film having an ionization potential of 8.5×10⁻¹⁹ J or below.

2. The organic EL element according to claim 1, wherein the ionization potential of the organic-thin-film-forming-molecules of the first organic thin film is lower than that of the second organic thin film by 3.2×10⁻²⁰ J or above.

3. The organic EL element according to claim 1, wherein the first organic thin film has a career concentration of 5×10¹⁸ (1/cm³) or above.

4. The organic EL element according to claim 1, wherein the organic-thin-film-forming-molecules of the first organic thin film are water-insoluble.

5. The organic EL element according to claim 1, wherein the organic-thin-film-forming-molecules of the first organic thin film have a molecular weight of 1,000 or above.

6. The organic EL element according to claim 1, wherein the dopants of the first organic thin film comprise organic acid.

7. The organic EL element according to claim 6, wherein the dopants of the first organic thin film comprise a benzenesulfonic acid derivative.

8. The organic EL element according to claim 1, wherein the dopants in the first organic thin film have a molecular weight of 10,000 or below.

9. The organic EL element according to claim 1, wherein the first organic thin film comprises a thin film, which is disposed by applying a liquid containing the organic-thin-film-forming-molecules and the dopants.

10. An organic EL display device comprising a plurality of organic EL elements defined in claim 1.

11. A method for fabricating an organic EL element, comprising disposing an anode on a substrate, disposing an organic EL layer in contact with the anode, and disposing a cathode in contact with the organic EL layer;
the step for disposing the organic EL layer comprising:
applying a liquid on the anode to dispose a first organic thin film in contact with the anode, the liquid containing organic-thin-film-forming-molecules and dopants oxidizing the organic-thin-film-forming-molecules; and
disposing a second organic thin film in contact with the first organic thin film;
the dopants in the first organic thin film having a reduction potential of 0.5 to 0.85 V with respect to a standard hydrogen electrode; and
the second organic thin film having an ionization potential of 8.5×10⁻¹⁹ J or below.
